(19) United States
(12) Patent Application Publication
(10) Pub. No.: US 2021/0405611 A1
(43) Pub. Date: Dec. 30, 2021

(54) Virtual computerized numerical control machine system and method

(71) Applicant: SendItCNC, Inc., San Francisco, CA (US)

(72) Inventor: Franklin David Boswell, San Francisco, CA (US)

(21) Appl. No.: 17/359,536

(22) Filed: Jun. 26, 2021

Related U.S. Application Data
(60) Provisional application No. 63/045,825, filed on Jun. 29, 2020.

(51) Int. Cl. G05B 19/4069; G06F 30/20

(52) U.S. Cl. CPC G05B 19/4069; G06F 30/20; G05B 2219/35212; G05B 2219/35026; G05B 2219/33099

(57) ABSTRACT

A virtual computer numerical control (CNC) machining system includes: a virtual CNC design server, including a work-holding library and workpiece library; a virtual CNC manufacturing server, including a CNC Machine library and a machining tool library; a virtual CNC manufacturing device; a virtual CNC machine job, including a logical workpiece, a design model, a logical work-holding device, a logical machining tool, a logical CNC machine, and a logical machine job; a plurality of physical CNC machine systems, each including a physical CNC machine, and physical work-holding devices, machining tools, and work pieces. Also disclosed is a virtual CNC machining method, including installing CNC machine systems; creating, editing, validating, translating, and calculating cost of a logical machine job; and manufacturing.

### CROSS-REFERENCE TO RELATED APPLICATIONS

This application claims the benefit of U.S. Provisional Application No. 63/045,825, filed Jun. 29, 2020; which is hereby incorporated herein by reference in its entirety.

### FIELD OF THE INVENTION

The present invention relates generally to the field of parts manufacture using computerized numerical control machine, and more particularly to methods and systems for shared access to computerized numerical control machines based on computer aided design and computer aided manufacturing models provided by users.

### BACKGROUND OF THE INVENTION

Methods presently in use for designing parts using CAD/CAM (Computer Aided Design and Computer Aided Manufacturing) systems often rely on attributes representing features and specifications of real-world CNC (Computer Numerical Control) machines, which are manufacturing machines such as lathes and milling machines) in designs. CAD/CAM systems include, at a minimum, a CAD (Computer Aided Design) system and a CAM (Computer Aided Manufacturing) system, which may be from the same vendor or different vendors, with sufficient integration or adherence to common standards to permit them to be used together.

The workflow for design and preparation for CNC fabrication of a physical object that was designed in a CAD/CAM system is described here to provide background and context for the various embodiments of the present invention. This description is also intended to define terms that are necessary to the description of the various embodiments of the present invention.

A CAD (Computer Aided Design) system enables a user (“CAD designer”) to create a 3-dimensional model (the “CAD model”) of an object. The output of a CAD system is a digital representation of the CAD model which is stored in a computer. Elements of the model, such as surfaces, edges, contours and holes are referred to as “features”. CAD systems may make available to their users various libraries representing objects designed by others, and of interest to the present invention such libraries may contain models of possible workholding devices, and models of possible raw material pieces for potential use with CAM programs. Further, CAD systems may provide the ability to make available to their users various packages (“add-ins”) by third parties which provide functionality beyond that offered as an integrated part of the CAD system and which may be beneficial to the CAD designer.

A CNC machine is a machine typically intended for use in the fabrication of objects and generally operates by means of movement and operation of a tool relative to a workpiece. CNC machines are designed to perform the operations specified in CNC programs. The prevalent language for CNC programs is G-code, which is a computer language that comprises instructions for the control of CNC machines, such as cutting tool selection and workpiece movement. A CNC machine is necessarily controlled by a computer (the “CNC controller”) which is an integral part of the CNC machine. The term “tool” as it is applied here means devices including, without loss of generality, rotating cutters (milling), non-rotating cutters (lathe), measuring probes, laser cutters and markers, plasma cutters, electrical discharge cutters, waterjet cutters, and material deposition devices. Tools have numerous attributes, including for example, specifications for their geometry such as overall tool length, cutting edge length, diameter, shape, and number of cutting edges. Examples of CNC machines include CNC milling machines, CNC routers, CNC lathes, CNC mill-turn machines and 3D printers.

Movement, which is fundamental to CNC machines and therefore G-code, is described in terms of a multi-dimensional coordinate system, which is used to define locations such as that of a tool relative to a workpiece (typically using Cartesian coordinates) and further is used to define the orientations such as that of a tool relative to a workpiece (typically using one or more additional rotational axes). The term “workpiece” refers to an object which is being operated on by the tools. G-Code also provides instructions to operate other features of CNC machines; for example, selecting a tool and mounting it in a spindle, turning spindles which rotate tools or workpieces on and off, selecting speeds for rotating spindles, turning coolant systems on and off, and starting and stopping chip evacuation systems. There are many manufacturers of CNC machines and although there is a standard for the G-code language, each manufacturer implements somewhat different G-code functionality and consequently a somewhat different G-code dialect, arising in part from manufacturers' proprietary extensions to the language which may be necessary to support particular manufacturer's unique machine features.

A CAM (Computer Aided Manufacturing) system enables a user (“CAM designer”) to define a sequence of operations (the “CAM program”) which are intended to create a real physical rendition of a CAD model, when those operations are performed on a workpiece by a CNC machine. The CAM system takes as its input the CAD model, as well as a description of some aspects of the CNC machine on which the CAM program is intended to operate. That description includes details of the tools available, typically including, for example, the geometric shape of the tool, the surface speed at which tool should operate, and how fast the tool can be moved when engaged with the workpiece.

The term “operation”, as it is applied in the context of CAM, generally refers to the application of a tool to a workpiece to contribute to the formation of the object defined by a CAD model. CAM systems typically provide a range of different operations, such as “drill a hole”, or “cut along a contour”. Each operation requires specification of a number, possibly large, of attributes; for example, the tool to be used, the relevant features from the CAD model for the operation, the relevant regions of the workpiece, and a specification of the motion by which the tool should approach the workpiece. A simple example is that one of the CAM operations could be a “drill” operation, have attributes including the tool (a drill of a particular size), the location and orientation of the hole in the CAD model, the spindle rpm, and the rate at which the drill should be fed into the material. There are many possible CAM operations with considerably more complexity than a drilling operation, for example machining a 3-dimensional surface, and numerous (often hundreds) attributes that specify the details of the operation. The available CAM operations and attributes may vary depending on CAM System. Many of the CAM operation attributes are numeric or a selection from a small range of values, but some specify features in the CAD design, or a tool to be used for the operation.

Generally, when using a CAM system, the user need not write G-code programs, but instead can specify the actions of the CNC machine by specifying CAM operations, which is generally considered to be easier and less error prone than G-code programming. CAM systems must produce G-code programs for execution by a specified manufacturer's CNC machine, and the G-code program would typically be somewhat different for each manufacturers CNC machine. The approach often taken is to produce a file of generic CNC operations which is then translated by a “post processor” to the G-code dialect for the desired target CNC machine, and provide a set of post-processors (one for each G-code dialect).

However, experienced CAD/CAM designers and the CNC machinists who are tasked with running the G-code programs ultimately created from such systems know that there are considerable risks when running newly-created G-code programs for the first time. Since the CNC machine is a powerful robot which is simply following the instructions in the G-code program, it can quickly and easily do catastrophic and expensive damage to the CNC machine itself or high-value workpieces. In practice, it is often mandatory for new G-code programs to be “proven” (meaning tested for safety), for example by careful manual observation of the program running without actual material in the machine (“cutting air”), or with the tools well distanced from other machine parts, or by running very slowly or a single operation step at a time. This is a time consuming, tedious and error prone process, and particularly troublesome in circumstances where new G-code programs are frequently encountered, such as when fabricating prototypes or low quantity production runs of diverse ranges of parts.

In current practice, jobs may be presented to a CNC machine operator with numerous elements implied or unspecified, relying instead on the knowledge and experience of the operator to make suitable decisions to define the aspects of the job necessary to proceed with its safe execution. The omissions encountered in current practice, and the corresponding decisions and responsibility implicitly pushed to the CNC machinist can be considerable and have correspondingly sizeable implications for the risks of adverse outcomes.

As such, considering the foregoing, it may be appreciated that there continues to be a need for novel and improved devices and methods for shared access to computerized numerical control machines.

### SUMMARY OF THE INVENTION

The foregoing needs are met, to a great extent, by the present invention, wherein in aspects of this invention, enhancements are provided to the existing model of for shared access to computerized numerical control machines.

In an aspect, a virtual computer numerical control (CNC) machining system, can include:
a) a virtual CNC design server, which can be configured to create and edit a virtual CNC machine job, including:
   i. a logical workpiece, which specifies a physical workpiece;
   ii. a design model, which specifies a manufactured piece for manufacturing from the physical workpiece; and
   iii. a logical work-holding device, which specifies a physical work-holding device for holding the physical workpiece during the manufacturing;
b) a virtual CNC manufacturing server, which can be configured to edit the virtual CNC machine job, wherein the virtual CNC machine job further includes:
   i. a logical machining tool, which specifies a physical machining tool for machining the manufactured piece;
   ii. a logical CNC machine, which specifies a physical CNC machine for manufacturing the manufactured piece, when the physical work-holding device with the physical workpiece attached and the physical machining tool are mounted on the physical CNC machine; and
   iii. a logical machine job, which specifies a sequence of logical machine operations for manufacturing the physical workpiece with specifications according to the design model; and
c) a Virtual CNC manufacturing device, which can be configured to enable a user to access the virtual CNC design server and the virtual CNC manufacturing server.

In a related aspect, the virtual computer numerical control (CNC) machining system, can further include:
a) the physical CNC machine, further including:
   i. the physical work-holding device with the physical workpiece attached; and
   ii. the physical machining tool.

In another related aspect, the virtual computer numerical control (CNC) machining system, can further include:
a) a plurality of physical CNC machine systems, wherein each corresponding physical CNC machine system includes:
   i. a corresponding physical CNC machine;
   ii. a plurality of physical work-holding devices, each configured to be mounted on the corresponding physical CNC machine; and
   iii. the physical machining tool.

There has thus been outlined, rather broadly, certain embodiments of the invention in order that the detailed description thereof herein may be better understood, and in order that the present contribution to the art may be better appreciated. There are, of course, additional embodiments of the invention that will be described below and which will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings. The invention is capable of embodiments in addition to those described and of being practiced and carried out in various ways. In addition, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is a schematic diagram illustrating a virtual CNC machining system, according to an embodiment of the invention.

FIG. 2 is a schematic diagram illustrating a virtual CNC design server, according to an embodiment of the invention.

FIG. 3 is a schematic diagram illustrating a virtual CNC manufacturing server, according to an embodiment of the invention.

FIG. 4 is a schematic diagram illustrating a virtual CNC manufacturing device, according to an embodiment of the invention.

FIG. 5 is a schematic diagram illustrating a CAD/CAM workflow with Virtual CNC Machine usage added, including the relationship of the assets which define Virtual CNC Machines to the typical CAD/CAM workflow, and the Virtual CNC Machine Job to Physical CNC Machine Job transformation process step.

FIG. 6 is a schematic diagram illustrating a process of capturing a Virtual CNC Machine Job.

FIG. 7 is a schematic diagram illustrating a process of transformation of a Virtual CNC Machine Job to a Physical CNC Machine Job.

FIG. 8 is a schematic diagram illustrating a sub-process of validation and, diagnosis and correction of Virtual CNC Machine Job CAM operation attributes, occurring within the overall process of transforming a Virtual CNC Machine Job to a Physical CNC Machine Job.

FIG. 9 is a flowchart illustrating steps that may be followed, in accordance with one embodiment of a method or process of virtual CNC machining.

### DETAILED DESCRIPTION

Before describing the invention in detail, it should be observed that the present invention resides primarily in a novel and non-obvious combination of elements and process steps. So as not to obscure the disclosure with details that will readily be apparent to those skilled in the art, certain conventional elements and steps have been presented with lesser detail, while the drawings and specification describe in greater detail other elements and steps pertinent to understanding the invention.

The following embodiments are not intended to define limits as to the structure or method of the invention, but only to provide exemplary constructions. The embodiments are permissive rather than mandatory and illustrative rather than exhaustive.

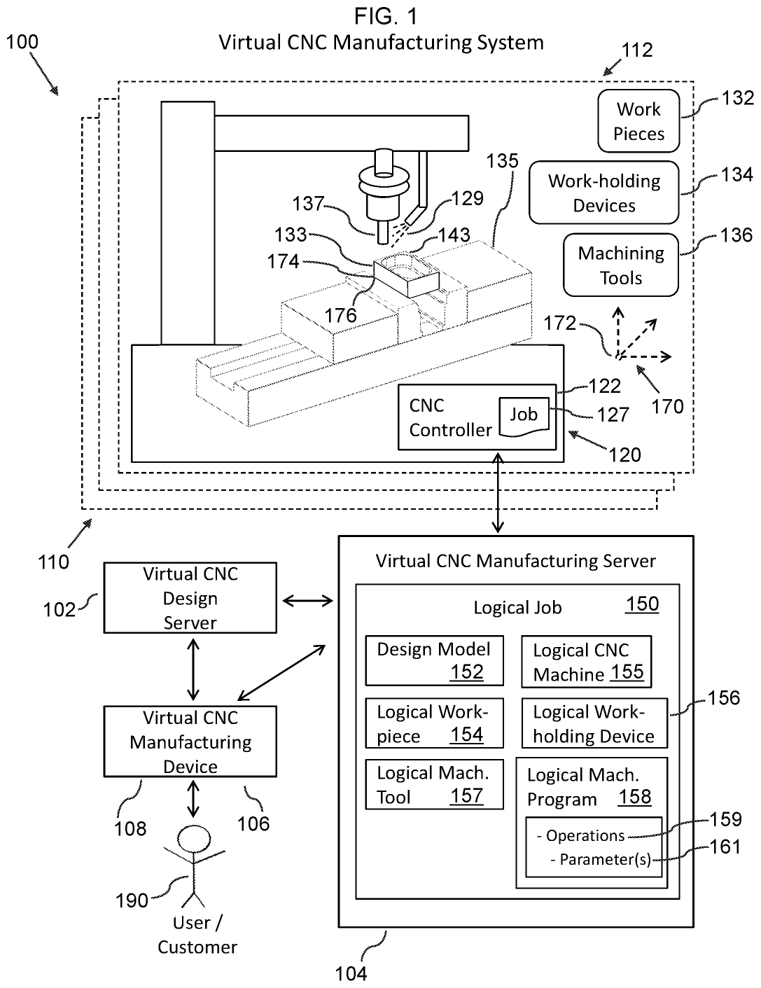

In the following, we describe the structure of embodiments of virtual computer numerical control (CNC) machining system 100 with reference to FIG. 1, in such manner that like reference numerals refer to like components throughout; a convention that we shall employ for the remainder of this specification.

In various embodiments, the virtual CNC machining system 100 can provide increased reliability, predictability and ease of use to CAD/CAM users by providing logical/virtual CNC machines for use in the design process, and subsequent transformation of the resulting designs to a form suitable for processing on physical CNC machines, during which transformation process error checking, diagnosis and correction are performed.

In related embodiments, specifications for a physical CNC Machine 120 can include many physical parameters, for example, the lengths and orientation of the axes of movement which the CNC machine 120 provides, the speeds and acceleration of the axes and cutting spindles, and perhaps hundreds of other such parameters which together describe the capabilities of the particular CNC machine 120. A Virtual/Logical CNC Machine 155 (as distinct from a Physical CNC Machine 120) can be a set of specifications for a CNC machine which does not necessarily directly correspond to any particular Physical CNC machine 120. Compared to a Physical CNC Machine 120, the definition of a Virtual CNC Machine 155 can incorporate restrictions and simplifications in its specifications, and also extensions beyond the capabilities of any particular Physical CNC Machine 120. A virtual CNC machine 155 can also be called a logical CNC machine 155.

In related embodiments, fabrication work can be packaged for execution on CNC machines as jobs, which include the CAD/CAM design and supporting specifications. Typically, such supporting specifications include the description of the cutting tools required, the raw material required (material, shape, size), the workholding method description (e.g. a milling machine vise of a certain size), and the relationship between the geometric coordinate system of the CAD/CAM design and the coordinate system of the CNC machine.

In a further related embodiment, a Virtual/Logical CNC Machine Job 150 includes a CAD/CAM design together with supporting information which specifies the intended virtual machine, and cutting tools, raw material, and workholding selections from those which are available with the intended virtual machine. Further, a Physical CNC Machine Job 127 is complete and ready for execution by a CNC control unit 122 on a particular Physical CNC Machine 120, and in particular all necessary machine-specific features (for example the activation of coolant and chip evacuation subsystems) are present as part of the G-code program, and the safety validation of the CAD/CAM program has been evaluated and found to be acceptable, and all necessary specifications required to run the program are available to the CNC machine operator. A virtual CNC machine job 150 can also be called a logical machine job 150.

In various related embodiments, the virtual CNC machining system 100 can provide CAD/CAM designers with abstract, idealized Virtual CNC Machines 155 for use in the design process. The present invention implements a transformation from a Virtual CNC Machine Job 150 to a Physical CNC Machine Job 127, during which transformation process error checking, diagnosis and correction are performed, yielding increased reliability, predictability and ease of use. Key benefits that can be achieved generally arise from the CAD/CAM designer 190 working with a well-defined, idealized, simplified, abstract Virtual CNC machine and can include:
a) Restrictions which are enforced by the methods and software of the present invention considerably reduce the risks associated with running newly-created G-code programs. This can be beneficial in the iteration of prototype designs where each design revision generates a new “unproven” G-code program. Virtual/Logical CNC Machines 155 are designed to simplify the process of determining that a set of CAM operations is of sufficiently low risk to run on a particular CNC machine;
b) Complexities arising from the allocation of the resources of Physical CNC Machines can be hidden from CAD/CAM designers 190, and automated. For example, a single large CNC machine 120 may be used to realize multiple smaller Virtual CNC Machines 155 fabricating a varying range of diverse parts, however the CAD/CAM designer need not be concerned with the multi-tenancy of the real machine, they simply see their own private Virtual CNC Machine. This can be useful to shops running a varying mix of parts on a set of real machines with diverse capabilities. Further, the actual virtual machine capabilities used by the CAM program can be assessed, providing greater flexibility in the allocation of Virtual CNC Machine Jobs 150 to real machines;
c) Certain Virtual CNC Machines 155 capabilities can exceed those of Physical CNC Machines 120, particularly in terms of flexibility and convenience. For example, virtual tools can be provided to the CAM designer which are later mapped by the software to real tools at which time tool attributes are established appropriate to the material being worked and the operation being performed, thus freeing the CAD/CAM designer from involvement with the minutiae of tool attribute specification. Tool-related specifications typically include spindle RPM (“speed”) and the rate at which the tool is moved through the material (“feed”), amongst numerous other possible parameters. That these details are tedious, repetitive and error prone is evidenced by the industry application of the term “speeds and feeds” as a pejorative for obscure, low-level detail; and
d) The Virtual CNC Machine 155 is designed to make it feasible to provide CNC capabilities over computer networks (local, wide area and internet), and in particular to enable Virtual CNC Machine services to be offered to remote parties without the need for physical presence.

Generally, in various related embodiments, designing for a Virtual CNC Machine 155 can be both more restrictive in some aspects, as a result of enforcing disciplines intended to increase the predictability and reliability of execution of the CNC program; and less restrictive in other aspects, as it frees the designer from certain detail, principally related to real-world CNC machining.

In a related embodiment, the virtual CNC machining system 100 can implement a transformation (i.e. a compilation/translation) from a Virtual CNC Machine Job 150 to a Physical CNC Machine Job 127, wherein the Virtual CNC job 150 is error-checked and corrected, and allocated to a Physical CNC Machine and rendered in a form complete and suitable for execution by a CNC Control Unit/Controller 122 on a particular Physical CNC Machine, whereby a CNC machine operator does not need to determine missing specifications and make decisions on such missing specifications.

In related embodiments, the virtual CNC machining system 100 can be implemented in conjunction with CAD/CAM software package(s) that the virtual CNC machining system 100 can be intended to complement and extend, and may include:
a) Software “add-ins” for the CAD system;
b) Software “add-ins” for the CAM system;
c) Custom post-processors for the CAM system;
d) Software programs, including software operating in a web or internet environment which may interact with users, and which interact with the CAD/CAM software or operate on the files used by the CAD/CAM software; and/or
e) Libraries specifying workholding models, workpiece models, Virtual CNC Machine descriptions, tools, and CAM operation templates in a form which is usable by the CAD/CAM system and the software which transforms Virtual CNC Machine Jobs 150 to Physical CNC Machine Jobs 127.

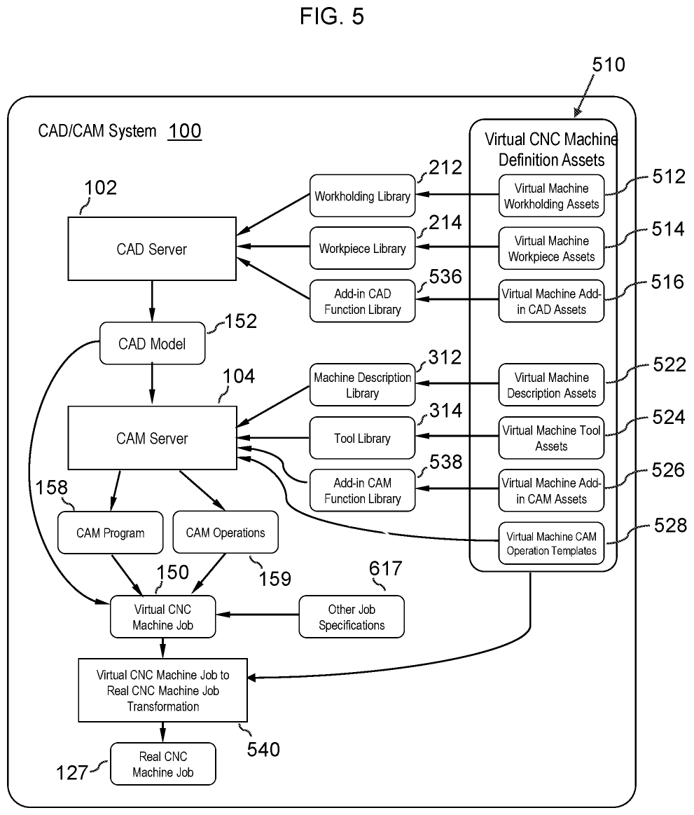

In a related embodiment, as shown in FIG. 5, A Virtual CNC Machine 155 can be manifested to a user 190 of a CAD/CAM system as including a collection of virtual/logical machine definition assets 510, which define the necessary attributes of a Virtual CNC Machine to permit design of CAD/CAM programs for that machine, wherein the virtual machine definition assets 510 can include:
a) Virtual/logical Machine Workholding Assets 512, which are CAD Models of physical workholding devices 134, which represent the means by which a part may be held during fabrication on the Virtual CNC Machine. Examples include vises, dovetail holders, and lathe chucks. It is possible that a workholding device may include functionality such as a 4th axis rotary device which extends the functionality of the Virtual CNC Machine by adding an extra axis for orienting the workpiece relative to the tool. The models for workholding devices generally include a reference point for locating workpieces relative to workholding devices. Note that the Virtual CNC Machine Workholding Asset models do not necessarily correspond directly to any particular real devices, but instead are mapped to real devices as available and sufficient at the time of transformation 540 to a Physical CNC Machine Job 127. Each Virtual Machine Workholding Asset has an associated estimated fixed cost and cost per unit time;
b) Virtual/logical Machine Workpiece Assets 514, which are CAD models representing possible original pieces of material 132 (e.g., a length of bar stock from a foundry or mill) from which a part is cut, or built upon, which are available on the Virtual CNC Machine. There may be a large number of different possible workpiece models representing the shapes and sizes of real material stock available. The models for workpieces generally include a reference point for locating workpieces relative to workholding devices. Each Virtual Machine Workpiece Asset has an associated estimated fixed cost;
c) Virtual/logical Machine Add-in CAD Assets 516, which are additional function modules that provide automation assistance to the user for creating CAD programs which conform to the requirements of the Virtual CNC Machine, and can be added to an Add-In CAD Function Library 536. For example, an add-in may be provided which assists in the insertion of an appropriate workholding device and workpiece in the user's CAD model;
d) Virtual/logical Machine Description Asset 522, which are specifications describing the Virtual CNC Machine's capabilities, typically include at a minimum a description of the geometry and motion capabilities of the machine but may include detail on a range of aspects of the machine. This may include geometric and dimensional specifications for the axes of motion of the Virtual CNC Machine, the acceleration and velocity capabilities of the axis drive systems, the speed, power and location of the spindles, and other capabilities of the machine. Generally, the definition of a Virtual CNC Machine is intended to be idealized and less complex than the description of a Physical CNC Machine. The Virtual Machine Description Asset has an associated estimated fixed cost and cost per unit time;
e) Virtual/logical CNC Tool Assets 524, which are definitions of the physical cutters/machining tools 136, in the case of subtractive manufacturing (e.g. lathe cutting tools, milling cutting tools, plasma cutting tools, water-jet cutting tools) or, in the case of additive manufacturing (3-d printing), the material deposition tools, available on the Virtual CNC Machine. Tool descriptions typically include not only the specification of the tool itself, but also the tool holder. Virtual CNC Machine tools do not necessarily have a simple one-to-one correspondence with Physical CNC Machine tools. For example, a virtual CNC cutter may have no specification for certain properties (e.g. number of cutting edges, material, cutter diameter), and these unspecified parameters are left to be determined subsequently when the virtual cutter is mapped to a real cutter for a particular operation on a particular real machine. Depending on the capabilities of the CAD/CAM system, virtual cutters may be represented to the user as a tool with a name which by convention defines it as such; for example (“Virtual End Mill”) where the text “Virtual” in the cutter description identifies it as such. Further, although such tools may have an apparently-complete set of attributes present in the CAD/CAM system, those attributes will be superseded during the transformation process 540 to a Physical CNC Machine Job 127. Each Virtual Machine Tool Asset has an associated estimated fixed cost and cost per unit time;
f) Virtual/logical Machine Add-in CAM Assets 526, which are additional function modules that provide automation assistance to the user for creating CAM programs which conform to Virtual CNC Machine requirements, and can be added to an Add-In CAM Function Library 538; and
g) Virtual/logical Machine CAM Operation Templates 528, which define acceptable parameters for the attributes of CAM operations on the Virtual CNC Machine.

In related embodiments, the Virtual Machine Definition Assets 510 can be made available to the CAD/CAM designer 190, and their utilization in the system 100 can be required to ensure error-free transformation of a Virtual CNC Machine Job 150 to a Physical CNC Machine Job 127.

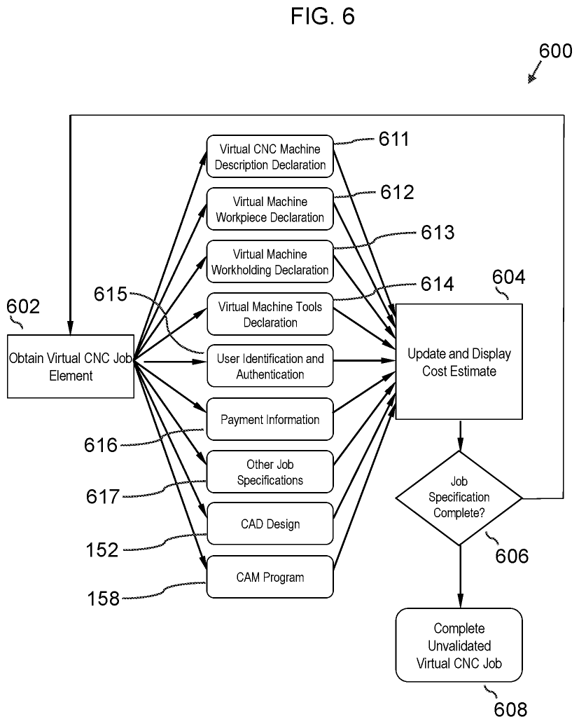

In a related embodiment, as shown in FIG. 6, a virtual/logical CNC machine job 150 can include:
a) A Virtual/logical CNC Machine description declaration 611;
b) A Virtual/logical CNC Machine workpiece declaration 612;
c) A Virtual/logical CNC Machine workholding declaration 613;
d) A Virtual/logical CNC Machine tools declaration (typically a subset of the tools available) 614;
e) An Identification 615 of the user submitting the job 150;
f) A payment method 616 associated with the job 150;
g) Other specifications 617, which are associated with the job 150, which can for example include: quantity of parts, submission time and date, expected completion time, and/or date
h) CAD design file(s) 152; and
i) CAM program file (s) 158 (including the estimated run-time for the CAM program provided by the CAM software, also including the estimated run-time for each tool).

In a related embodiment, the cost of running a Virtual CNC Machine Job 150 can be estimated based on the Virtual CNC Machine Job specifications 510 by summing the costs associated with the Virtual CNC Machine 155, workholding devices 613, and tools 614 for the estimated run times, the workpiece 612, and any costs associated with the other specifications 617 provided, taking into account any pricing entitlements (for example, discounts) associated with the user submitting the job 150.

In a related embodiment, as shown in FIG. 6, a method 600 for receiving a Virtual CNC Machine Job 150 can include a Virtual CNC Job Capture process, which permits a user to interactively provide the specifications comprising a Virtual CNC Machine Job. This process may be implemented as an application to run on a computer, an application to run in a browser, an application to run on a mobile device, or an application programming interface (API) which can be accessed by other computer software, and can include:
a) Until the Virtual CNC Job 150 is complete, The Virtual CNC Job Capture process accepts 602 a series of digital files or digital input entered by a user, which the user declares to represent the specifications comprising a virtual CNC job 150;
b) Updating and displaying 604 cost estimates for the virtual CNC job 150;
c) The Virtual CNC Job Capture process validates 606 the overall completeness, but not the semantic validity of the Virtual Machine Job 150, and where the job 150 is incomplete, solicits further elements of the Job 150 in order to complete it; and
d) The virtual CNC Job Capture Process authenticates the user represented to it and will not complete 608 creation of the virtual CNC Job 150 without an authenticated user.

In a related embodiment, the virtual CNC machining system 100 can transform a Virtual CNC Machine Job 150 (represented digitally) to a Physical CNC Machine Job 127. The virtual CNC machining system 100 examines the declarations and specification comprising the Virtual CNC Machine Job 150 to determine the validity of the job 150, provides diagnostic information, where possible corrects errors which would otherwise make the job 150 invalid, and then renders the job 150 in a form suitable for running in an actual machine shop on a Physical CNC Machine 120, in order to fabricate the part.

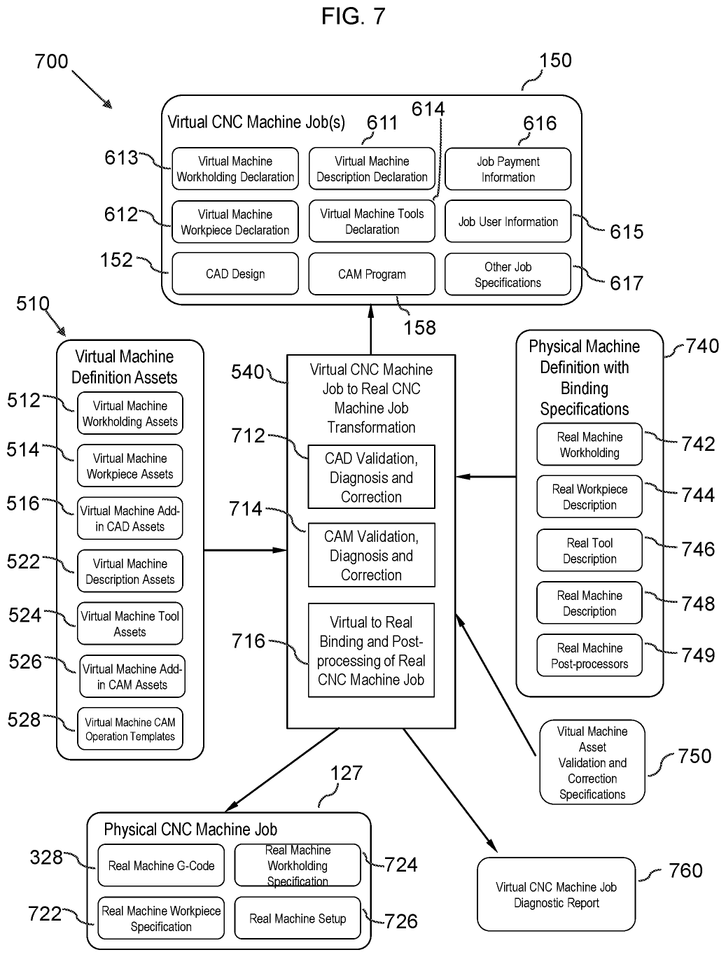

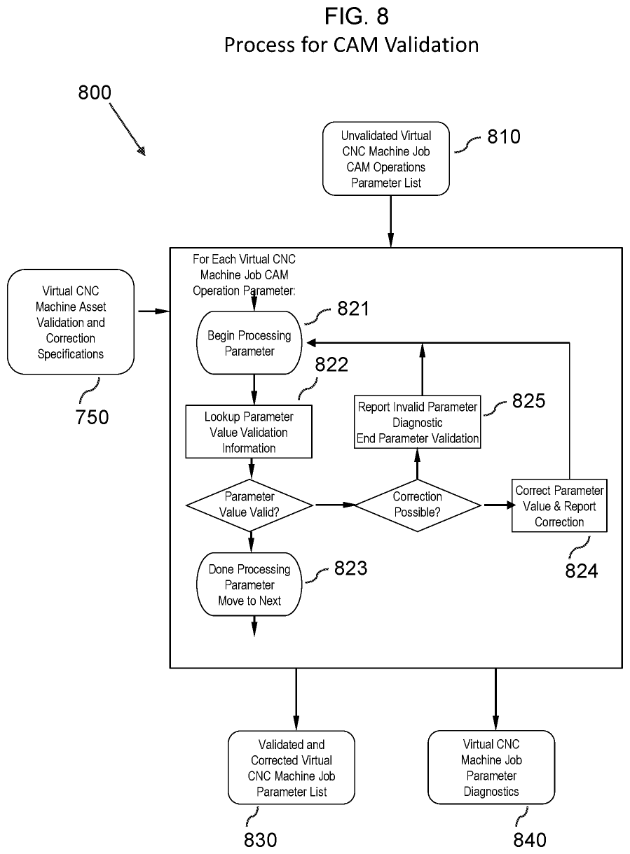

In another related embodiment, as shown in FIGS. 7 and 8, a method 700 for transforming 540 a Virtual CNC Machine Job 150 into a Physical CNC Machine Job 127 (the “Realization” of the Virtual CNC Machine Job 150) can include processes, including: first CAD and CAM Validation, Diagnosis and Correction 712, 714, and then Virtual to Real Binding and Post-processing 716.

In a further related embodiment CAD and CAM Validation, Diagnosis and Correction 712, 714 can include:
a) The Validation, Diagnosis and Correction process examines a complete but unvalidated Virtual CNC Machine Job 150 represented digitally and provides diagnostic information regarding the validity of the job 150, and where possible corrects defects in the job 150. The Validation, Diagnosis and Correction process uses the Virtual Machine Definition Assets and the Virtual Machine Asset Validation and Correction specifications 750, which are represented as digital files, to enable its processing;
b) The Validation, Diagnosis and Correction process performs the following specific functions, generating diagnostic messages in the Virtual CNC Machine Job Diagnostic Report 760 for all corrections and errors:
   i. Validation that the Virtual CNC Machine description declaration in the Virtual CNC Machine Job declaration conforms to a Virtual CNC Machine specification from the Virtual Machine Description Assets.
   ii. Validation that the extents of movement in the Virtual CNC Machine Job CAM program fall with the extents of movement possible with the declared Virtual CNC Machine description.
   iii. Validation that the CAD model corresponding to the Virtual CNC Machine workpiece declaration is present and unaltered from its original form in the Virtual CNC Machine Job CAD model. If the workpiece model is found to have been altered, then a correction may be applied by deleting the modified model and replacing it with the unaltered version located at the same position relative to the workpiece model reference point;
   iv. Validation that the CAD model corresponding to the Virtual CNC Machine workholding declaration, is present and unaltered in the Virtual CNC Machine Job CAD model. If the workholding model is found to have been altered, then a correction may be applied by deleting the modified model and replacing it with the unaltered version located at the same position relative to the workholding model reference point;
   v. Validation that the workpiece model reference point is coincident with the workholding model reference point;
   vi. Validation that the Work Coordinate System defined in the CAM program uses the axis definitions of the workholding model and the origin identified as the WCS Origin Reference point in the workholding model;
   vii. Validation that each tool used in the CAM program is unaltered from a tool found in the tool library referenced in the Virtual CNC Machine tools declaration. If a tool is found to have been altered, then a correction may be applied by deleting the modified tool and replacing it with the unaltered version;
   viii. Validation that the CAM program simulates without collision;
   ix. Validation that the CAM program simulates within cutter load limits;
   x. Validation that the User information in the Virtual CNC Machine Job 150 specifications represent a user with authority to submit the job;
   xi. Validation of the payment method in the Job specification represents a valid payment method;
   xii. Validation that all attributes of all CAM operations of the CAM program conform to the Virtual CNC Machine Asset Validation and Correction Specifications 750, as more fully described below;
   xiii. Correction of any invalid attributes of the CAM program according to Virtual CNC Machine Asset Validation and Correction Specifications 750, where possible, as more fully described below; and/or
   xiv. In order to provide meaningful and helpful diagnostics, validation of conformance to certain CAM operation protocols (e.g. presence of drilling operation prior to tapping) is performed. This permits defects which would have been diagnosed with a general diagnostic (such as “excess cutting load” or “tool collides with workpiece”) to be given a more insightful diagnosis (“no hold drilled prior to tapping”).

In a related embodiment, a process for validating CAM operation attributes 800, as shown in FIG. 8 can use a file 750 which can include, without limitation, a digital specification of a range of acceptable values for each possible attribute/parameter of each possible CAM operation (as shown in Virtual Machine Asset Validation and Correction Specifications 750 of FIG. 7). For CAM attributes/parameters with values, which are selected from a set of possible values, this file contains the set of acceptable values. For CAM attributes which are numeric values, this file contains arithmetic expressions for the upper and lower bounds of the ranges of acceptable values, such expressions being of the form implemented by the applicable CAD/CAM system. This file further contains for each attribute a digital specification for the possibility of correction in the case of an invalid value and a specification, again in the form of a value or an arithmetic expression, for such correction, if possible.

Thus, in a related embodiment, as shown in FIG. 8, the process for validating CAM operation attributes 800 can include: For each parameter 810 of each CAM operation in the CAM program 821, the attribute value is examined and compared 822 to the range of acceptable values specified in the Virtual Machine Asset Validation and Correction Specifications 750 to determine validity. If the attribute value is found to be invalid, then if correction is possible the value is corrected 824 according to the specification in the Virtual Machine Asset Validation and Correction Specifications file 750 and the correction is reported in the diagnostics file. If an invalid attribute is found with no correction possible then the attribute validation process fails 825, and the virtual CNC job is invalid. If the attribute value is found to be valid, then parameter processing completes 823 and moves to the next parameter. The process 800 completes with a Validated and Corrected Virtual CNC Machine Job Parameter List 830 and a Virtual CNC Machine Job Parameter Diagnostics Report 840, with information of invalid parameters and corrections.

In a further related embodiment, the Virtual Machine Asset Validation and Correction Specifications file 750 can further include, for each possible CAM operation, a set of attribute/parameter values for a set of virtual tools supported for that operation. For each attribute of each virtual tool found in an operation in the CAM program, the attributes of virtual tool can be established from values from the Virtual Machine Asset Validation and Correction Specifications file 750 corresponding to the CAM operation and virtual tool, and if no matching virtual tool specification exist the validation process fails, and the Virtual CNC Machine Job is invalid.

In a related embodiment, as shown in FIGS. 7 and 8, Virtual to Real Binding and Post-processing can include:
a) mapping of the elements of the Virtual CNC Machine Job 150 to real world elements to create a corresponding Physical CNC Machine Job 127. This mapping can be referred to as a “binding” and it is performed based on the Virtual CNC Machine Job specifications and Physical Machine Definition with Binding Specifications file 740, wherein the binding phase can include:
   i. Binding 748 of the Virtual CNC Machine Job 150 to a Physical CNC Machine 120, and more particularly to a work area with the Physical CNC Machine 120;
   ii. Binding 742 of Virtual CNC Machine workholding devices to Physical CNC Machine workholding devices;
   iii. Binding 744 of Virtual CNC Machine workpieces to real stock material;
   iv. Binding of Virtual CNC Machine Job CAM program coordinate systems to Work Coordinate Systems of the Physical CNC Machine;
   v. Binding 746 of Virtual CNC Machine cutting, depositions and probing tools to Physical CNC Machine tools;
   vi. Augmentation 749 of the Virtual CNC Machine Job CAM program with necessary real machine operations, including for example but without limitation coolant type selection, coolant start/stop, airblast start/stop, chip removal start/stop, safety device control, and probing; and
   vii. Post-processing 749 to generate Physical CNC Machine code 159 (typically G-code) for the particular Physical CNC Machine to which the Virtual CNC Job is bound, subject to the bindings established.

In a further related embodiment, multiple Virtual CNC Machine Jobs 150 may be aggregated into a single Physical CNC Machine job 127. For example, a particular Physical CNC Machine 120 may be sufficiently capable to permit the execution of multiple Virtual CNC Machine Jobs (either multiple instances of the same job of multiple different jobs) pseudo-concurrently, in which case the Virtual CNC Machine Job may allocated to a fraction of the Physical CNC Machine. Such multiplexing can be done in both the space domain (several small virtual machine jobs can share a large real machine) and the time domain (several virtual machine jobs can take turns sharing a single real machine resource such as a spindle).

In a related embodiment, the information necessary to enable the virtual to real binding of validated Virtual CNC Machine Jobs can be represented digitally in the Real Machine Definition with Binding Specifications file, which contains a list of available Physical CNC Machines, which each can include:
a) A specification of the physical parameters of the Physical CNC Machine, including the lengths and orientation of the axes of movement, the speeds and acceleration of the axes;
b) Available work areas on each Physical CNC Machine, including the size, location and orientation for each work area. For example, a simple 3-axis mill may have a single work area with physical extents corresponding to the real machine's work envelope, and which may allow utilization as multiple smaller work areas, and a 5-axis mill with a “pyramid” or “tombstone” setup might have numerous 3-axis work areas;
c) Specifications for available workholding devices on the Physical CNC Machine, and their available locations in work areas on the machine;
d) Specifications for available tools on the Physical CNC Machine;
e) Cost information, both fixed and per unit time, for the operation of the Physical CNC Machine, its possible workholding devices, and its available tools;
f) Specifications for other operations available on the Physical CNC Machine including, without limitation, coolant systems and chip evacuation systems; and
g) Specifications for the actuation of other operations at particular points in time during the executing of CAM operations.

In a further related embodiment, binding can be performed on a set of validated Virtual CNC Machine Jobs and a set of Physical CNC Machines described in a Real Machine Definition with Binding Specifications file. This can be done by searching the Real Machine Definition with Binding Specifications file for Physical CNC Machine work areas that match the requirements represented by the Virtual CNC Machine Job declarations, subject to constraints including:
a) the work areas must accommodate the spatial requirements for the Virtual CNC Machine Job;
b) the work areas must have real workholding devices available which meet the requirements for the Virtual CNC Machine Job workholding declaration; and
c) The Physical CNC Machine must have real tools available which meet the requirements for the Virtual CNC Machine Job tools declaration.

In various related embodiment, many potential binding arrangements can be available and in such cases the arrangements can be ranked according to their quality relative to an optimization metric, for example but without limitation, cost minimization or lateness minimization. In a simple case, a single Virtual CNC Machine Job can be bound to a single Physical CNC Machine, and no optimization may be necessary or even possible.

In further related embodiments, the binding of Virtual CNC Machine Jobs to Physical CNC Machine work areas determines the Physical CNC Machine locations (work offsets in the real machine coordinate system) for the virtual jobs.

In a related embodiment, the actual CNC code (typically G-code) can be generated from the Virtual CNC Machine Job CAM programs, as corrected and augmented by the transformation process. This function may be performed using a post processor definition for the chosen real machine, which has been extended to perform aspects of the transformation of a Virtual CNC Machine Job to a Physical CNC Machine Job. At the time of the post processing step, setup information 726 can be created for the operator tasked with running the Physical CNC Machine Job, specifying the tools required in the Physical CNC Machine, the real workholding device 724 and its location in the Physical CNC Machine, and the size and shape of raw material/workpiece 722 to be used and its location in the workholding device.

Thus, in various related embodiments, the virtual CNC machining system 100 can include the following enumerated embodiments:
1) A virtual CNC machining system 100 which receives a Virtual CNC Machine Job description over a global communication network;
2) The virtual CNC machining system 100 of embodiment 1), further comprising the ability to receive the Virtual CNC Machine Job description by means of an interactive web interface, mobile application, or computer application which communicates with a user, or an API (Application Programming Interface) which communicates with another computer program representing a user;
3) The virtual CNC machining system 100 of embodiment 1), further comprising the ability to display estimated costs for material, machining time, tools and workholding, thus providing an immediate job-cost estimate based on the Virtual CNC Machine Job description received, the estimated costs associated with the declarations of the Virtual CNC Machine Job for machine, workpiece, workholding, tools and CAM design, and the associated machining time estimate provided by the CAM system;
4) The virtual CNC machining system 100 of embodiment 1), further comprising the ability to collect user identification information pertaining to the Virtual CNC Machine Job, and perform authentication on such user information;
5) The virtual CNC machining system 100 of embodiment 1), further comprising the ability to collect payment information with the Virtual CNC Machine Job, to be processed subsequently at the time of corresponding Physical CNC Machine Job execution;
6) A virtual CNC machining system 100, which processes a Virtual CNC Machine Job to determine the validity the Virtual CNC Machine Job and whether or not it is acceptable for execution, where validation can include, at least one, or a combination or all of:
   i. Validation that the Virtual CNC Machine description declaration in the Virtual CNC Machine Job declaration conforms to a Virtual CNC Machine specification from the Virtual Machine Description Assets;
   ii. Validation that the extents of movement in the Virtual CNC Machine Job CAM design fall with the extents of movement possible with the declared Virtual CNC Machine description;
   iii. Validation that the model corresponding to the Virtual CNC Machine workpiece declaration is present and unaltered from its original form in the Virtual CNC Machine Job CAD design;
   iv. Validation that the model corresponding to the Virtual CNC Machine workholding declaration is present and unaltered in the Virtual CNC Machine Job CAD design;
   v. Validation that the workpiece model reference point is coincident with the workholding model reference point;
   vi. Validation that the Work Coordinate System defined in the CAM program uses the axis definitions of the workholding model and the origin identified as the WCS Origin Reference point in the workholding model;
   vii. Validation that each tool used in the CAM program is unaltered from a tool found in the tool library referenced in the Virtual CNC Machine Tools declaration;
   viii. Validation that the CAM program simulates without collision;
   ix. Validation that the CAM program simulates within cutter load limits;
   x. Validation that the User information in the Job specifications represent a user with authority to submit the job;
   xi. Validation of the payment method in the Job specification represents a valid payment method;
   xii. Validation that all attributes of all CAM operations of the CAM program conform to the Virtual CNC Machine Asset Validation and Correction Specifications 750, as shown in FIG. 8; and/or
   xiii. In order to provide meaningful and helpful diagnostics, validation of conformance to certain CAM operation protocols (e.g. presence of drilling operation prior to tapping) is performed. This permits defects which would have been diagnosed with a general diagnostic (such as “excess cutting load” or “tool collides with workpiece”) to be given a more insightful diagnosis (“no hole drilled prior to tapping”);
7) The virtual CNC machining system 100 of embodiment 6), further comprising the ability to apply corrections to validation errors where possible
8) The virtual CNC machining system 100 of embodiment 6), further comprising the ability to provide diagnostic information to the user specifying the findings of the validation and correction process
9) The virtual CNC machining system 100 of embodiment 6), further comprising the ability to provide proposed corrections to the user and accept user input indicating the user's preference in accepting the proposed corrections or rejecting the proposed corrections and aborting transformation of the Virtual CNC Machine Job.
10) The virtual CNC machining system 100 of embodiment 6), further comprising the ability to deliver Virtual CNC Machine Definition Assets to a user by a global computer network, where such assets are the specifications for Virtual CNC Machines for which implementations of the method of embodiment 6) exist, and where such assets may include some of all of the following: Virtual Machine Description Assets, Virtual Machine Workholding Assets, Virtual Machine Workpiece Assets, Virtual Machine Tool Assets, Virtual Machine Add-in CAM Assets, Virtual Machine Add-in CAD Assets, and Virtual Machine Operation Templates. Such definitions may be packaged as digital files, software or a combination of both.
11) A virtual CNC machining system 100 which transforms validated Virtual CNC Machine Jobs into Physical CNC Machine Jobs for execution on particular Physical CNC Machines, and rendering such Physical CNC Machine Jobs in a form suitable for execution on such machine, together with all supporting specifications necessary for such execution 12) The virtual CNC machining system 100 of embodiment 11), further comprising the ability to resolve real-machine-specific specifications required for rendering of a Physical CNC Machine Job, and which specifications are not present as part of the corresponding Virtual CNC Machine Job, based on the Virtual CNC Machine Job specification and Physical CNC Machine feature availability, including
   i. The activation and deactivation of coolant flow;
   ii. The activation and deactivation of mist coolant;
   iii. The activation and deactivation of through-spindle coolant flow;
   iv. The activation and deactivation of compressed air blast;
   v. The activation and deactivation of through-spindle compressed air blast;
   vi. Tool measurement;
   vii. Tool breakage detection;
   viii. Workpiece probing to establish work coordinate system;
   ix. The activation and deactivation of chip removal systems; and
   x. The operation of real machine attributes relating to precision vs. speed tradeoffs;
13) The virtual CNC machining system 100 of embodiment 11), further comprising the ability to resolve real-world cutter specifications required for rendering of a Physical CNC Machine Job, and which specifications may not necessarily be present as part of the corresponding Virtual CNC Machine Job, including cutter diameter, cutter shape, cutter type and other cutter properties based on Virtual CNC Machine Job information including CAM program, material, cost preference, cutter availability, and feature availability on a particular Physical CNC Machine;
14) The virtual CNC machining system 100 of embodiment 11), further comprising the automatic refactoring of a single toolpath into multiple toolpaths, for example, substituting a combination of roughing and finishing toolpaths for a single toolpath; and
15) The virtual CNC machining system 100 of embodiment 11), wherein the allocation of Virtual CNC Machine Jobs to a Physical CNC Machine admits the allocation of multiple Virtual CNC Machine Jobs to a single Physical CNC Machine simultaneously, with Physical CNC Machine resources shared among the allocated jobs by time-domain and space-domain multiplexing.

Thus, in an embodiment, as shown in FIG. 1, a virtual computer numerical control (CNC) machining system 100, can include:
a) a virtual CNC design server 102, which can be configured to create and edit a logical machine job 150, including:
   a logical workpiece 154, which specifies a physical workpiece 133; and
   a design model 152, which specifies a manufactured piece 143 for manufacturing from the physical workpiece 133;
   a logical work-holding device 156, which specifies a physical work-holding device 135 for holding the physical workpiece 133 during the manufacturing;
b) a virtual CNC manufacturing server 104, which can be configured to edit the logical machine job 150, wherein the logical machine job 150 can further include:
   a logical machining tool 157, which specifies a physical machining tool 137 for machining the manufactured piece 143;
   a logical CNC machine 155, which specifies a physical CNC machine 120 for manufacturing the manufactured piece 143, when the physical work-holding device 135 with the physical workpiece 133 attached and the physical machining tool 137 are mounted on the physical CNC machine 120;
   a logical machine program 158, which includes a sequence of logical machine operations 159 for manufacturing the manufactured piece 143 with specifications according to the design model 152; and
c) a virtual CNC manufacturing device 108, which can be configured to enable a user 190 to access the virtual CNC design server 102 and the virtual CNC manufacturing server 104.

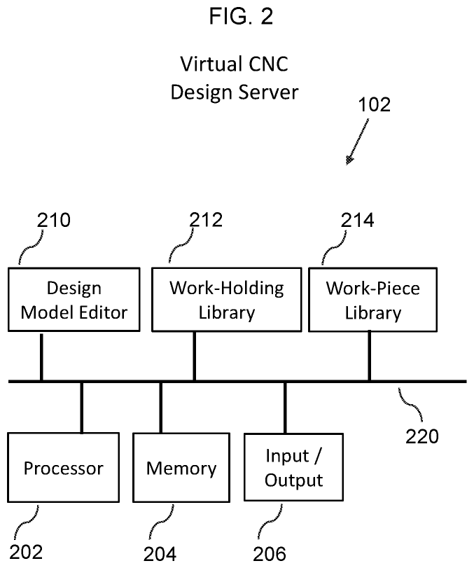

In a related embodiment, as shown in FIG. 2, a virtual CNC design server 102 can include:
a) A processor 202;
b) A non-transitory memory 204;
c) An input/output component 206; and
d) A design model editor 210, which can be configured to create and edit design parts of a logical job 150; all connected via
e) A data bus 220.

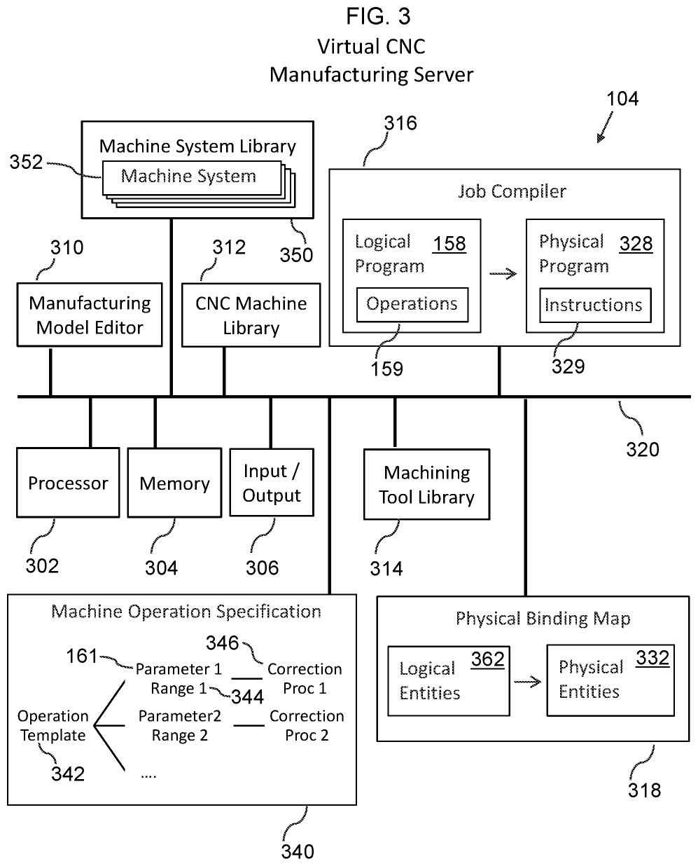

In a related embodiment, as shown in FIG. 3, a virtual CNC manufacturing server 104 can include:
a) A processor 302;
b) A non-transitory memory 304;
c) An input/output component 306;
d) A manufacturing model editor 310, which can be configured to create and edit manufacturing parts of the logical job 150;
e) A CNC machine library 312; and
f) A machining tool library 314; all connected via
g) A data bus 320.

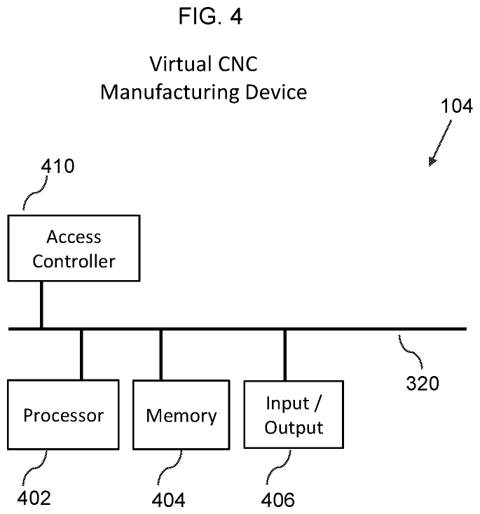

In a related embodiment, as shown in FIG. 4, a virtual CNC manufacturing device 108 can include:
a) A processor 402;
b) A non-transitory memory 404;
c) An input/output 406; and
d) An access controller 410, which can be configured to enable a user 190 to access the virtual CNC design server 102 and the virtual CNC manufacturing server 104; all connected via
e) A data bus 320.

In a related embodiment, the virtual computer numerical control (CNC) machining system 100, can further include:
a) the physical CNC machine 120, further including:
   i. the physical work-holding device 135 with the physical workpiece 133 attached; and
   ii. the physical machining tool 137.

In another related embodiment, the virtual computer numerical control (CNC) machining system 100, can further include:
a) A plurality 110 of physical CNC machine systems 112, wherein each physical CNC machine system 112 can include:
   i. a corresponding physical CNC machine 120;
   ii. a plurality 134 of physical work-holding devices 135, each configured to be mounted on the corresponding physical CNC machine 120;
   iii. a plurality 136 of physical machining tools 137, each configured to be mounted on the corresponding physical CNC machine 120; and
   iv. a plurality 132 of physical work pieces 133, each configured to be machined when mounted in the physical work-holding device 135 on the corresponding physical CNC machine 120.

In yet another related embodiment, the virtual CNC design server 102 can further include:
a) a work-holding library 212, which includes:
   i. a plurality of logical work-holding devices 156;
wherein the virtual CNC design server 102 can be configured to select the logical work-holding device 156 from the work-holding library 212.

In yet another related embodiment, the virtual CNC manufacturing server 104 can further include:
a) a CNC Machine library 312, which includes:
   i. a plurality of logical CNC machines 155;
wherein the virtual CNC manufacturing server 104 can be configured to select the logical CNC machine 155 from the CNC machine library 312.

In a related embodiment, the virtual CNC design server 102 can further include:
a) a workpiece library 214, which comprises:
   i. a plurality of logical workpieces 154, each corresponding to a corresponding physical workpiece;
wherein the virtual CNC design server 102 can be configured to select the logical workpiece 154 from the workpiece library 214.

In a further related embodiment, the logical workpieces can include:
a) Initial/raw logical workpieces (such as corresponding to rectangular pieces of metal or other source); and
b) Work-in-progress logical workpiece, which each can be an output of a prior logical job 150, which can have taken as input an initial/raw logical workpiece or a prior work-in-progress logical workpiece.

In a related embodiment, the virtual CNC manufacturing server 104 can further include:
a) a machining tool library 312, which comprises:
   i. a plurality of logical machining tools 157, each corresponding to a corresponding physical machining tool 137;
wherein the virtual CNC manufacturing server 104 can be configured to select the logical machining tool 157 from the machining tool library 312.

In another related embodiment, as shown in FIG. 3, the virtual CNC manufacturing server 104 can further include a machine system library 350, which can include:
a) A plurality of logical CNC machine systems 352, wherein each corresponding logical CNC machine system 352 can include:
   i. a corresponding logical CNC machine 155;
   ii. a plurality of logical work-holding devices 156, each configured to be compatible with the corresponding logical CNC machine 155;
   iii. a plurality of logical machining tools 157, each configured to be compatible with the corresponding logical CNC machine 155; and
   iv. a plurality of logical work pieces 154, each configured to be compatible with the corresponding logical CNC machine 155;
wherein each logical machine system 352 in the plurality of logical CNC machine systems 352 corresponds to a corresponding physical CNC machine system 112 in the plurality of physical CNC machine systems 112;
such that the virtual CNC manufacturing device 108 can be configured to enable a user 190 to download a selected logical CNC machine system 352 from the machine system library 350 on the virtual CNC manufacturing server 104, such that the selected logical CNC machine system 352 can be used as a starting point for creating (and editing) a logical machine job 150.

In yet a related embodiment, the logical machine job 150 can further include:
a) a logical CNC machine declaration 611, which specifies the logical CNC machine 155 to be used for the logical machine job 150;
b) a logical workpiece declaration 612;
c) a logical workholding declaration 613;
d) a logical tools declaration 614, which specifies a set of selected tools 137;
e) a design model 152; and
f) a logical machine program 158, which includes the sequence of logical machine operations 159, wherein an estimated run-time can be associated with each logical machine operation 159.

In a further related embodiment, the logical machine job 150 can further include:
a) a user identification 615, which identifies a user 190 submitting the logical machine job 150; and
b) a payment method 616.

In another further related embodiment, the logical machine job 150 can further include a logical CNC machine declaration 611, which specifies the logical CNC machine 155 to be used for the logical machine job 150;

wherein the virtual CNC manufacturing server 104 can further include logical machine description assets 522, which comprise logical CNC machine specifications for the logical CNC machine declaration 611.

In a yet further related embodiment, the virtual CNC manufacturing server 104 can be configured to execute a job validation of the logical machine job, wherein the job validation can include:
a) a machine validation, which validates that specifications of the logical CNC machine 155 of the logical machine job 150 conform to the logical CNC machine specifications of the logical machine description assets 522.

In another further related embodiment, the logical CNC machine specifications can further include a range of possible movements for the logical CNC machine declaration 611; such that the virtual CNC manufacturing server 104 can be configured to execute a job validation of the logical machine job 150, wherein the job validation comprises:
a) a movement validation, which validates that a range of required movements in the logical machine operations 159 of the logical machine program 158 are within the range of possible movements specified in the logical CNC machine specifications of the logical machine description assets 522. The required movements can also be referred to as the “bounding box” of the of the logical machine program. The possible movements of the logical CNC machine can also be referred to as the “movement envelope” of the of the logical CNC machine.

In yet a further related embodiment, the logical machine job 150 can further include a logical workpiece declaration 612, which specifies the logical workpiece 154 to be used for the logical machine job 150;

wherein the virtual CNC manufacturing server 104 can further include logical workpiece description assets 514, which comprise logical workpiece specifications for the logical workpiece declaration 612;
wherein the virtual CNC manufacturing server 104 can be configured to execute a job validation of the logical machine job 150, wherein the job validation comprises:
a) a workpiece validation, which validates that specifications of the logical workpiece of the logical machine job 150 conform to the logical workpiece specifications of the logical workpiece description assets 514.

In yet a further related embodiment, the logical machine job 150 can further include a logical work-holding device declaration 613, which specifies the logical work-holding device 156 to be used for the logical machine job 150;

wherein the virtual CNC manufacturing server 104 can further include logical work-holding description assets 512, which include logical work-holding device specifications for the logical work-holding device declaration 613;
wherein the virtual CNC manufacturing server 104 can be configured to execute a job validation of the logical machine job 150, wherein the job validation comprises:
a) a work-holding validation, which validates that specifications of the logical work-holding device of the logical machine job 150 conform to the logical work-holding device specifications of the logical work-holding description assets 512.

In a further related embodiment, the logical workholding device specifications can further include axis definitions and an origin reference point, wherein the virtual CNC manufacturing server 104 is configured to execute a job validation of the logical machine job 150, wherein the job validation can include:
a) a coordinate system validation, which validates that a work coordinate system 170 defined in the logical machine job 150 conforms with the axis definitions of the logical workholding device specifications of the logical work-holding description assets 512, such that an origin 172 of the work coordinate system 170 coincides with the origin reference point of the logical workholding device specifications of the logical work-holding description assets 512.

In another further related embodiment, the virtual CNC manufacturing server 104 can be configured to execute a job validation of the logical machine job, wherein the job validation comprises:
a) a reference point validation, which validates that a geometric reference point 174 of the logical workpiece 154 is coincident with a geometric reference point 176 of the logical work-holding device 156, with respect to positioning specified in the logical machine program 158 of the logical machine job 150.

In another further related embodiment, the logical machine job can further include a logical tool declaration 614, which specifies the logical tool 157 to be used for the logical machine job 150;

wherein the virtual CNC manufacturing server 104 can further include logical tool description assets 524, which comprise logical tool specifications for the logical tool declaration 614;
wherein the virtual CNC manufacturing server is configured to execute a job validation of the logical machine job, wherein the job validation comprises:
a) A tool validation, which validates that specifications of the logical tool of the logical machine job 150 conform to the logical tool specifications of the logical tool description assets 524.

In a yet further related embodiment, the job validation can further include:
a) a no-collision validation, which validates that the logical machine job 150 simulates without collision, such that the virtual CNC manufacturing server 104 performs a controlled execution of the sequence of logical machine operations 159 of the logical machine program 158 (such as by executing a step-by-step emulation/interpretation/simulation of the sequence of logical machine operations 159), to validate that each logical machine operation 159:
   i. does not cause a collision of the logical machining tool 157 with the logical work-holding device 156;
   ii. does not cause an unplanned collision of the logical machining tool 157 with the logical work-piece 154; and
   iii. does not cause a collision of the logical machining tool 157 with the logical CNC machine 155 (although in most cases such collisions are not possible due to control/safety mechanisms of the physical CNC machine 120).

In another yet further related embodiment, the job validation can further include:
a) a load-limit validation, which validates that the logical machine job 150 simulates within cutter load limits, such that the virtual CNC manufacturing server 104 performs a controlled execution of the sequence of logical machine operations 159 of the logical machine program 158 (such as by executing a step-by-step emulation/interpretation/simulation of the sequence of logical machine operations 159), to validate that each logical machine operation 159:
   i. executes such that a maximum cutting load on the logical machining tool 157 when simulating cutting of the logical workpiece 154 is within a predetermined maximum load threshold for the logical machining tool 157.

In further related embodiments, the controlled execution of the sequence of logical machine operations 159, performed during the job validation, can be a traversal of the sequence of logical machine operations 159 of the logical machine program 158, which can be a step-by-step (i.e. operation-by-operation) interpretation (or emulation) of the sequence of logical machine operations 159 of the logical machine program 158, according to conventional language interpreter methods; or the traversal can use other methods of static and/or dynamic semantic code analysis. Similarly, the controlled execution can be implemented using similar methods used in graphical or non-graphical code-debugging, sometime also referred to as code-simulation.

In another further related embodiment, as shown in FIG. 3, a job compiler 316 of the virtual CNC manufacturing server 104 can be configured to execute a program translation of the logical machine job 150 to a physical machine job 127, wherein the program translation can include:
a) executing a step-by-step traversal of the sequence of logical machine operations 159 of the logical machine program 158, such that each logical machine operation 159 is translated into a corresponding sequence of machine instructions 329 of a physical machine program 328 (of the physical job 127) for the physical CNC machine 120;
whereby the physical machine job 127 is configured to be executed on a CNC control unit/controller 122 on the physical CNC machine 120.

In a further related embodiment, as shown in FIG. 3, the virtual CNC manufacturing server can further include a physical binding map 318, which for each logical CNC machine system 352 specifies a mapping from logical entities to physical entities in a corresponding physical CNC machine system 112, which comprises the physical CNC machine 120; wherein the job compiler 316 of the virtual CNC manufacturing server 104 can be further configured to perform a replacement of each logical entity reference 362 in the corresponding sequence of machine instructions 329 with a physical entity reference 332, according to a match in the physical binding map 318, such that each logical entity reference 362 matches with at least one physical entity reference 332, wherein the match can be a lookup returning a physical entity reference 332, or a pattern matching or other type of matching operation.

In related embodiments, a logical entity reference 362 can include a logical reference to a logical CNC machine 155, to a logical workpiece 154, to a logical work-holding device 156, to a logical machining tool 157, or to other logical entities. A physical entity reference 332 can include a physical reference to a physical CNC machine 120, to a physical workpiece 133, to a physical work-holding device 135, to a physical machining tool 137, or to other logical entities; wherein the physical entity reference 332 can be defined in an operating environment of the physical CNC machine 120, i.e. within an operating system of the CNC control unit/controller 122 of the physical CNC machine 120.

In a yet further related embodiment, the program translation of the job compiler 316 can be further configured to determine further specifications 742, 744, 746, 748, which are associated with the physical entity reference, wherein the further specifications can be retrieved from stored specifications in a physical machine definitions and binding specifications file 740 stored on the virtual CNC manufacturing server 104, wherein the stored specifications are associated with the physical entity reference. Such further specifications may not be explicitly specified by the corresponding logical entity reference, but are only determined after binding to a physical entity reference. Such further specifications can for example specify cutter diameter, cutter shape, cutter type, etc.

In related embodiments, the physical binding map 318 can permit many-to-one mappings from logical to physical entities, such that several different logical entities can be mapped to one conforming physical entity. Similarly, the physical binding map 318 can permit one-to-many mappings from logical to physical entities, when there are a plurality of options available for conforming physical entities, which can then be prioritized according to availability, cost, etc.

Thus, in a further related embodiment, the program translation can be configured to determine a plurality of possible replacements for each logical entity reference 362 in the corresponding sequence of machine instructions 329, such that the plurality of possible replacements is a plurality of physical entity references 332, which are associated via the physical binding map 318.

In a further related embodiment, the program translation can further be configured to translate a logical machine operation 159 into a corresponding sequence of machine instructions 329 and an additional sequence of machine instructions 329 (including single instruction 329 sequences), which are not specified explicitly by the logical machine operation 159, wherein the additional sequence of machine instructions can be associated with a logical entity reference 362 associated with the logical machine operation 159, or can be associated with a physical entity reference 332 that is resolved during binding of the physical program. Such additional sequences of machine instructions 329 can for example provide liquid or air cooling, perform tool measurement and breakage detection, and/or perform work-piece probing (for example to establish coordinate references).

In a yet further related embodiment, the corresponding logical machine operation 159 can be a drilling operation, and the additional sequence of machine instructions 329, can include machine instructions 329 to activate and deactivate coolant flow 129 to a drill 137 used in the drilling operation.

In a further related embodiment, the virtual CNC manufacturing server 104 can be configured to estimate a cost of the logical machine job 150 by aggregating cost components, which can include:
a) a machine time share cost for the physical CNC machine 120, which is calculated as a function of (such as a product of) a total run time for the logical machine program 158 and a cost per unit of time (such as a cost per second) associated with the physical CNC machine 120, wherein the total run time for the logical machine program 158 can be calculated by aggregating run times for each step/operation 159 of the logical machine program 158;
b) a work-holding time share cost for the physical work-holding device 135, which is calculated as a function of (such as a product of) the total run time for the logical machine program 158 and a cost per unit of time (such as a cost per second) associated with the physical work-holding device 135;
c) a tool time share cost for the physical machining tool 137, which is calculated as a function of (such as a product of) the machining tool run time for the logical machine program 158 and a cost per unit of time (such as a cost per second) associated with the physical workpiece 133, wherein the machining tool run time for the logical machine program 158 can be calculated by aggregating run times for each operation 159 of the logical machine program 158, for operations 159 which utilize the logical machining tool 157; and
d) a workpiece cost for the physical workpiece 133.

In a further related embodiment, the virtual CNC manufacturing server 104 can be configured to calculate a cost of the physical machine job 127 by aggregating cost components, which can include:
a) a machine time share cost for the physical CNC machine 120, which is calculated as a function of (such as a product of) a total run time for the physical machine program 328 and a cost per unit of time (such as a cost per second) associated with the physical CNC machine 120, wherein the total run time for the physical machine program 328 can be calculated by aggregating run times for each instruction 329 of the physical machine program 328;
b) a work-holding time share cost for the physical work-holding device 135, which is calculated as a function of (such as a product of) the total run time for the physical machine program 328 and a cost per unit of time (such as a cost per second) associated with the physical work-holding device 135;
c) a tool time share cost for the physical machining tool 137, which is calculated as a function of (such as a product of) the machining tool run time for the physical machine program 328 and a cost per unit of time (such as a cost per second) associated with the physical workpiece 133, wherein the machining tool run time for the physical machine program 328 can be calculated by aggregating run times for each instruction 329 of the physical machine program 328, for instructions 329 which utilize the physical machining tool 137; and
d) a workpiece cost for the physical workpiece 133.

In a related embodiment, as shown in FIGS. 3 and 8, the virtual CNC manufacturing server 104 can further include a machine operations specification 340, which for each type of logical machine operation 159 can include a corresponding operation template 342, comprising a list of associated parameters 161, such that the corresponding operation template 342 for each associated parameter 161 comprises a permitted parameter range 344, which specifies values of operation parameters 161 that are permitted for execution of the operation 159 on the logical machine 155;

wherein the virtual CNC manufacturing server can be configured to perform an operation validation for each corresponding logical machine operation 159 of the logical machine program 158, if the corresponding operation template 342 comprises at least one parameter 161;
wherein the operation validation can be configured to validate that the at least one parameter 161 is within the permitted parameter range 344 associated with the at least one parameter in the corresponding operation template 342.

In a further related embodiment, as shown in FIGS. 3 and 8, the corresponding operation template 342 can further include a correction procedure 346, which is associated with the permitted parameter range 344 (or in general associated with a corresponding associated parameter 161);

such that the virtual CNC manufacturing server 104 can be configured to perform an operation correction 346 if the operation validation failed, using the correction procedure 346 of the corresponding operation template 342, such that the correction procedure 346 updates the at least one parameter 161 to be within the permitted parameter range 344 of the corresponding operation template 342. Such a correction may not always be possible, though, and in such cases the operation 159 can be flagged for manual correction by the user 190 (typically when there is no correction procedure 346 associated with the permitted range 344).

In a yet further related embodiment, the corresponding logical machine operation 159 can be a drilling operation; wherein the at least one parameter 161 can include a corresponding drill width parameter 161, which specifies a width of a drill; and

wherein the permitted parameter range 344 is specified from a minimum permitted drill width to a maximum permitted drill width;
such that the correction procedure 346 can be configured to update the corresponding drill width parameter 161 to the maximum permitted drill width, when the corresponding drill width parameter 161 is above the permitted parameter range 344; and
such that the correction procedure 346 can be configured to update the corresponding drill width parameter to the minimum permitted drill width, when the corresponding drill width parameter 161 is below the permitted parameter range 344.

In another yet further related embodiment, the corresponding logical machine operation 159 can be a drilling operation; wherein the at least one parameter 161 can include a corresponding dwell time parameter 161, which specifies a dwell time of the drill during the drilling operation, wherein the dwell time specifies the length of time the drill remains drilling in a lowest position, before retraction of the drill; and

wherein the permitted parameter range 344 is specified from a minimum permitted dwell time to a maximum permitted dwell time;
such that the correction procedure 346 can be configured to update the corresponding dwell time parameter 161 to the maximum permitted dwell time, when the corresponding dwell time parameter 161 is above the permitted parameter range 344; and
such that the correction procedure 346 can be configured to update the corresponding dwell time parameter to the minimum permitted dwell time, when the corresponding dwell time parameter 161 is below the permitted parameter range 344.

In another yet further related embodiment, the correction procedure 346 can be performed automatically, without intervention from a user 190.

In another yet further related embodiment, the correction procedure 346 can be performed subject to a manual confirmation from a user 190, wherein the correction procedure 346 is performed after the manual confirmation is provided by the user 190.

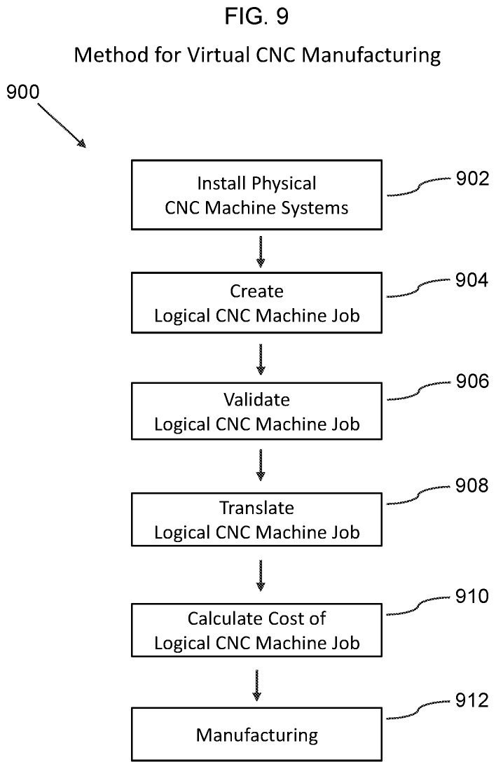

In an embodiment, as shown in FIG. 9, a method for virtual CNC manufacturing 900 can include:
a) installing 902 a plurality of physical CNC machine systems 112;
b) creating 904 and editing a logical machine job 150;
c) validating 906 the logical machine job 150, which can include:
   i. a machine validation;
   ii. a movement validation;
   iii. a workpiece validation;
   iv. a work-holding validation;
   v. a coordinate system validation;
   vi. a reference point validation;
   vii. a tool validation;
   viii. a no-collision validation;
   ix. a load-limit validation; and/or
   x. combinations of these;
d) translating 908 the logical machine job 150 to a physical machine job 127;
e) calculating 910 a cost of the logical machine job 150; and
f) manufacturing 912 a manufactured piece from a workpiece on a physical CNC machine executing the physical machine job 127.

In related embodiments, the Virtual CNC manufacturing device 108 can include configurations as:
a) A web application, for example executing in a Web browser;
b) A tablet app, executing on a tablet device, such as for example an ANDROID™ or IOS™ tablet device;
c) A mobile app, executing on a mobile device, such as for example an ANDROID™ phone or IPHONE™, or any wearable mobile device;
d) A desktop application, executing on a personal computer, or similar device;
e) An embedded application or embedded software, for example configured as a software plugin or module, executing on a processing device, such as for example a smart TV, a game console or any other computer system or device; and
f) Combinations thereof.

It shall be understood that an executing instance of an embodiment of the virtual CNC machining system 100, as shown in FIG. 1, can include a plurality of virtual CNC manufacturing devices 108, which are each tied to one or more users 190.

An executing instance of an embodiment of the virtual CNC machining system 100, as shown in FIG. 1, can similarly include a plurality of virtual CNC design servers 102 and a plurality of virtual CNC manufacturing servers 104.

FIGS. 1, 2, 3, 4, 5, 6, 7, 8, and 9 are block diagrams and flowcharts, methods, devices, systems, apparatuses, and computer program products according to various embodiments of the present invention. It shall be understood that each block or step of the block diagram, flowchart and control flow illustrations, and combinations of blocks in the block diagram, flowchart and control flow illustrations, can be implemented by computer program instructions or other means. Although computer program instructions are discussed, an apparatus or system according to the present invention can include other means, such as hardware or some combination of hardware and software, including one or more processors or controllers, for performing the disclosed functions.

In this regard, FIGS. 1, 2, 3, 4, and 5 depict the computer devices of various embodiments, each containing several of the key components of a general-purpose computer by which an embodiment of the present invention may be implemented. Those of ordinary skill in the art will appreciate that a computer can include many components. However, it is not necessary that all of these generally conventional components be shown in order to disclose an illustrative embodiment for practicing the invention. The general-purpose computer can include a processing unit and a system memory, which may include various forms of non-transitory storage media such as random access memory (RAM) and read-only memory (ROM). The computer also may include nonvolatile storage memory, such as a hard disk drive, where additional data can be stored.

FIG. 1 shows a depiction of an embodiment of virtual CNC machining system 100, including the virtual CNC design server 102, the virtual CNC manufacturing server 104, and the virtual CNC manufacturing device 108. In this relation, a server shall be understood to represent a general computing capability that can be physically manifested as one, two, or a plurality of individual physical computing devices, located at one or several physical locations. A server can for example be manifested as a shared computational use of one single desktop computer, a dedicated server, a cluster of rack-mounted physical servers, a datacenter, or network of datacenters, each such datacenter containing a plurality of physical servers, or a computing cloud, such as AMAZON EC2™ or MICROSOFT AZURE™.

It shall be understood that the above-mentioned components of the virtual CNC design server 102, the virtual CNC manufacturing server 104, and the virtual CNC manufacturing device 108 are to be interpreted in the most general manner.

For example, the processors 202, 302, 402 can each respectively include a single physical microprocessor or microcontroller, a cluster of processors, a datacenter or a cluster of datacenters, a computing cloud service, and the like.

In a further example, the non-transitory memories 204, 304, 404 can each respectively include various forms of non-transitory storage media, including random access memory and other forms of dynamic storage, and hard disks, hard disk clusters, cloud storage services, and other forms of long-term storage. Similarly, the input/outputs 206, 306, 406 can each respectively include a plurality of well-known input/output devices, such as screens, keyboards, pointing devices, motion trackers, communication ports, and so forth.

Furthermore, it shall be understood that the virtual CNC design server 102, the virtual CNC manufacturing server 104, and the virtual CNC manufacturing device 108 can each respectively include a number of other components that are well known in the art of general computer devices, and therefore shall not be further described herein. This can include system access to common functions and hardware, such as for example via operating system layers such as WINDOWS™, LINUX™, and similar operating system software, but can also include configurations wherein application services are executing directly on server hardware or via a hardware abstraction layer other than a complete operating system.

An embodiment of the present invention can also include one or more input or output components, such as a mouse, keyboard, monitor, and the like. A display can be provided for viewing text and graphical data, as well as a user interface to allow a user to request specific operations. Furthermore, an embodiment of the present invention may be connected to one or more remote computers via a network interface. The connection may be over a local area network (LAN) wide area network (WAN), and can include all of the necessary circuitry for such a connection.

In a related embodiment, the virtual CNC manufacturing device 108 communicates with the virtual CNC design server 102 and the virtual CNC manufacturing server 104 over a network 106, which can include the general Internet, a Wide Area Network or a Local Area Network, or another form of communication network, transmitted on wired or wireless connections. Wireless networks can for example include Ethernet, Wi-Fi, BLUETOOTH™, ZIGBEE™, and NFC. The communication can be transferred via a secure, encrypted communication protocol.

Typically, computer program instructions may be loaded onto the computer or other general-purpose programmable machine to produce a specialized machine, such that the instructions that execute on the computer or other programmable machine create means for implementing the functions specified in the block diagrams, schematic diagrams or flowcharts. Such computer program instructions may also be stored in a computer-readable medium that when loaded into a computer or other programmable machine can direct the machine to function in a particular manner, such that the instructions stored in the computer-readable medium produce an article of manufacture including instruction means that implement the function specified in the block diagrams, schematic diagrams or flowcharts.

In addition, the computer program instructions may be loaded into a computer or other programmable machine to cause a series of operational steps to be performed by the computer or other programmable machine to produce a computer-implemented process, such that the instructions that execute on the computer or other programmable machine provide steps for implementing the functions specified in the block diagram, schematic diagram, flowchart block or step.

Accordingly, blocks or steps of the block diagram, flowchart or control flow illustrations support combinations of means for performing the specified functions, combinations of steps for performing the specified functions and program instruction means for performing the specified functions. It will also be understood that each block or step of the block diagrams, schematic diagrams or flowcharts, as well as combinations of blocks or steps, can be implemented by special purpose hardware-based computer systems, or combinations of special purpose hardware and computer instructions, that perform the specified functions or steps.

As an example, provided for purposes of illustration only, a data input software tool of a search engine application can be a representative means for receiving a query including one or more search terms. Similar software tools of applications, or implementations of embodiments of the present invention, can be means for performing the specified functions. For example, an embodiment of the present invention may include computer software for interfacing a processing element with a user-controlled input device, such as a mouse, keyboard, touch screen display, scanner, or the like. Similarly, an output of an embodiment of the present invention may include, for example, a combination of display software, video card hardware, and display hardware. A processing element may include, for example, a controller or microprocessor, such as a central processing unit (CPU), arithmetic logic unit (ALU), or control unit.

Here has thus been described a multitude of embodiments of the virtual computer numerical control (CNC) machining system 100, and methods related thereto, which can be employed in numerous modes of usage.

The many features and advantages of the invention are apparent from the detailed specification, and thus, it is intended by the appended claims to cover all such features and advantages of the invention, which fall within the true spirit and scope of the invention.

For example, alternative embodiments can reconfigure or combine the components of the virtual CNC design server 102, the virtual CNC manufacturing server 104, and the virtual CNC manufacturing device 108. The components of the virtual CNC design server 102 and the virtual CNC manufacturing server 104 can be distributed over a plurality of physical, logical, or virtual servers. Parts or all of the components of the virtual CNC manufacturing device 108 can be configured to operate in the virtual CNC design server 102 and/or the virtual CNC manufacturing server 104, whereby the virtual CNC manufacturing device 108 for example can function as a thin client, performing only graphical user interface presentation and input/output functions. Alternatively, parts or all of the components of the virtual CNC design server 102 and/or the virtual CNC manufacturing server 104 can be configured to operate in the virtual CNC manufacturing device 108.

Many such alternative configurations are readily apparent, and should be considered fully included in this specification and the claims appended hereto. Accordingly, since numerous modifications and variations will readily occur to those skilled in the art, the invention is not limited to the exact construction and operation illustrated and described, and thus, all suitable modifications and equivalents may be resorted to, falling within the scope of the invention.

What is claimed is:

1. A virtual computer numerical control (CNC) machining system, comprising:
a) a virtual CNC design server, which is configured to create and edit a logical machine job, comprising:
a logical workpiece, which specifies a physical workpiece;
a design model, which specifies a manufactured piece for manufacturing from the physical workpiece; and
a logical work-holding device, which specifies a physical work-holding device for holding the physical workpiece during the manufacturing; and
b) a virtual CNC manufacturing server, which is configured to edit the logical machine job, wherein the logical machine job further comprises:
a logical machining tool, which specifies a physical machining tool for machining the manufactured piece;
a logical CNC machine, which specifies a physical CNC machine for manufacturing the manufactured piece, when the physical work-holding device with the physical workpiece attached and the physical machining tool are mounted on the physical CNC machine; and
a logical machine program, which comprises a sequence of logical machine operations for manufacturing the manufactured piece with specifications according to the design model.

2. The virtual CNC machining system of claim 1, further comprising:
the physical CNC machine, further comprising:
the physical work-holding device with the physical workpiece attached; and
the physical machining tool.

3. The virtual CNC machining system of claim 1, further comprising:
a plurality of physical CNC machine systems, wherein each physical CNC machine system comprises:
a corresponding physical CNC machine;
a plurality of physical work-holding devices, each configured to be mounted on the corresponding physical CNC machine;
a plurality of physical machining tools, each configured to be mounted on the corresponding physical CNC machine; and
a plurality of physical work pieces, each configured to be machined when mounted on the corresponding physical CNC machine.

4. The virtual CNC machining system of claim 3, wherein the virtual CNC manufacturing server further comprises a machine system library, which comprises:
a plurality of logical CNC machine systems, wherein each logical CNC machine system comprises:
a corresponding logical CNC machine;
a plurality of logical work-holding devices, each configured to be compatible with the corresponding logical CNC machine;
a plurality of logical machining tools, each configured to be compatible with the corresponding logical CNC machine; and
a plurality of logical work pieces, each configured to be compatible with the corresponding logical CNC machine;
wherein each logical machine system in the plurality of logical CNC machine systems corresponds to a corresponding physical CNC machine system in the plurality of physical CNC machine systems.

5. The virtual CNC machining system of claim 4, further comprising:
a virtual CNC manufacturing device, which is configured to enable a user to access the virtual CNC design server and the virtual CNC manufacturing server;
such that the virtual CNC manufacturing device is configured to enable the user to download a selected logical CNC machine system from the machine system library on the virtual CNC manufacturing server, such that the selected logical CNC machine system is used as a starting point for creating the logical machine job.

6. The virtual CNC machining system of claim 1, wherein the logical machine job further comprises a logical CNC machine declaration, which specifies the logical CNC machine to be used for the logical machine job;
wherein the virtual CNC manufacturing server further comprises logical machine description assets, which comprises logical CNC machine specifications for the logical CNC machine declaration.

7. The virtual CNC machining system of claim 6, wherein the virtual CNC manufacturing server is configured to execute a job validation of the logical machine job, wherein the job validation comprises:
a machine validation, which validates that specifications of the logical CNC machine of the logical machine job conform to the logical CNC machine specifications of the logical machine description assets.

8. The virtual CNC machining system of claim 6, wherein the logical CNC machine specifications further comprises a range of possible movements for the logical CNC machine declaration;
wherein the virtual CNC manufacturing server is configured to execute a job validation of the logical machine job, wherein the job validation comprises:
a movement validation, which validates that a range of required movements in the logical machine operations of the logical machine program are within the range of possible movements specified in the logical CNC machine specifications.

9. The virtual CNC machining system of claim 6, wherein the logical machine job further comprises a logical workpiece declaration, which specifies the logical workpiece to be used for the logical machine job;
wherein the virtual CNC manufacturing server further comprises logical workpiece description assets, which further comprises logical workpiece specifications for the logical workpiece declaration;
wherein the virtual CNC manufacturing server is configured to execute a job validation of the logical machine job, wherein the job validation comprises:
a workpiece validation, which validates that specifications of the logical workpiece of the logical machine job conform to the logical workpiece specifications of the logical workpiece description assets.

10. The virtual CNC machining system of claim 6, wherein the logical machine job further comprises a logical work-holding device declaration, which specifies the logical work-holding device to be used for the logical machine job;
wherein the logical machine description assets further comprises logical work-holding device specifications for the logical work-holding device declaration;
wherein the virtual CNC manufacturing server is configured to execute a job validation of the logical machine job, wherein the job validation comprises:
a work-holding validation, which validates that specifications of the logical work-holding device of the logical machine job conform to the logical work-holding device specifications of the logical machine description assets.

11. The virtual CNC machining system of claim 10, wherein the logical workholding device specifications further comprises axis definitions and an origin reference point, wherein the virtual CNC manufacturing server is configured to execute a job validation of the logical machine job, wherein the job validation comprises:
a coordinate system validation, which validates that a work coordinate system defined in the logical machine job conforms with the axis definitions of the logical workholding device specifications, such that an origin of the work coordinate system coincides with the origin reference point of the logical workholding device specifications.

12. The virtual CNC machining system of claim 1, wherein the virtual CNC manufacturing server is configured to execute a job validation of the logical machine job, wherein the job validation comprises:
a reference point validation, which validates that a geometric reference point of the logical workpiece is coincident with a geometric reference point of the logical work-holding device, with respect to positioning specified in the logical machine program of the logical machine job.

13. The virtual CNC machining system of claim 6, wherein the logical machine job further comprises a logical tool declaration, which specifies the logical tool to be used for the logical machine job;
wherein the virtual CNC manufacturing server further comprises logical tool description assets, which comprise logical tool specifications for the logical tool declaration;
wherein the virtual CNC manufacturing server is configured to execute a job validation of the logical machine job, wherein the job validation comprises:
a tool validation, which validates that specifications of the logical tool of the logical machine job conform to the logical tool specifications of the logical tool description assets.

14. The virtual CNC machining system of claim 1, wherein the virtual CNC manufacturing server is configured to execute a job validation of the logical machine job, wherein the job validation comprises:
a no-collision validation, which validates that the logical machine job simulates without collision, such that the virtual CNC manufacturing server performs a controlled execution of the sequence of logical machine operations of the logical machine program, to validate that each logical machine operation:
does not cause a collision of the logical machining tool with the logical work-holding device; and
does not cause a collision of the logical machining tool with the logical CNC machine.

15. The virtual CNC machining system of claim 1, wherein the virtual CNC manufacturing server is configured to execute a job validation of the logical machine job, wherein the job validation comprises:
a load-limit validation, which validates that the logical machine job simulates within cutter load limits, such that the virtual CNC manufacturing server performs a controlled execution of the sequence of logical machine operations of the logical machine program, to validate that each logical machine operation:
executes such that a maximum cutting load on the logical machining tool when simulating cutting of the logical workpiece is within a predetermined maximum load threshold for the logical machining tool.

16. The virtual CNC machining system of claim 1, wherein the virtual CNC manufacturing server is configured to estimate a cost of the logical machine job by aggregating cost components, which comprise:
a) a machine time share cost for the physical CNC machine, which is calculated as a function of a total run time for the logical machine program and a cost per unit of time associated with the physical CNC machine;
b) a work-holding time share cost for the physical work-holding device, which is calculated as a function of the total run time for the logical machine program and a cost per unit of time associated with the physical work-holding device;
c) a tool time share cost for the physical machining tool, which is calculated as a function of the machining tool run time for the logical machine program and a cost per unit of time associated with the physical machining tool; and
d) a workpiece cost for the physical workpiece.

17. The virtual CNC machining system of claim 4, wherein the virtual CNC manufacturing server is configured to execute a program translation of the logical machine job to a physical machine job, wherein the program translation comprises:
executing a step-by-step traversal of the sequence of logical machine operations of the logical machine program, such that each logical machine operation is translated into a corresponding sequence of machine instructions for the physical CNC machine.

18. The virtual CNC machining system of claim 17, wherein the virtual CNC manufacturing server further comprises a physical binding map, which for each logical CNC machine system specifies a mapping from logical entities to physical entities in a corresponding physical CNC machine system, which comprises the physical CNC machine;
wherein the program translation is further configured to perform a replacement of each logical entity reference in the corresponding sequence of machine instructions with a physical entity reference, according to a match in the physical binding map.

19. The virtual CNC machining system of claim 18, wherein the program translation is configured to determine a plurality of possible replacements for each logical entity reference in the corresponding sequence of machine instructions, such that the plurality of possible replacements is a plurality of physical entity references, which are associated via the physical binding map.

20. The virtual CNC machining system of claim 18, wherein the program translation is further configured to translate a logical machine operation into the corresponding sequence of machine instructions and an additional sequence of machine instructions, wherein the additional sequence of machine instructions is associated with a logical entity reference associated with the logical machine operation.

21. The virtual CNC machining system of claim 20, wherein the corresponding logical machine operation is a drilling operation, and the additional sequence of machine instructions, comprises machine instructions to activate and deactivate coolant flow to a drill used in the drilling operation.

22. The virtual CNC machining system of claim 18, wherein the program translation is further configured to determine further specifications, which are associated with the physical entity reference, wherein the further specifications are retrieved from stored specifications on the virtual CNC manufacturing server, wherein the stored specifications are associated with the physical entity reference.

23. The virtual CNC machining system of claim 17, wherein the virtual CNC manufacturing server is configured to calculate a cost of the physical machine job by aggregating cost components, which comprise:
a) a machine time share cost for the physical CNC machine, which is calculated as a function of a total run time for the physical machine program and a cost per unit of time associated with the physical CNC machine;
b) a work-holding time share cost for the physical work-holding device, which is calculated as a function of the total run time for the physical machine program and a cost per unit of time associated with the physical work-holding device;
c) a tool time share cost for the physical machining tool, which is calculated as a function of the machining tool run time for the physical machine program and a cost per unit of time associated with the physical machining tool; and
d) a workpiece cost for the physical workpiece.

24. The virtual CNC machining system of claim 1, wherein the virtual CNC manufacturing server further comprises a machine operations specification, which for each type of logical machine operation comprises a corresponding operation template, comprising a list of associated parameters, such that the corresponding operation template for each associated parameter comprises a permitted parameter range;
wherein the virtual CNC manufacturing server is configured to perform an operation validation for each corresponding logical machine operation of the logical machine program, if the corresponding operation template comprises at least one parameter;
wherein the operation validation is configured to validate that the at least one parameter is within the permitted parameter range associated with the at least one parameter in the corresponding operation template.

25. The virtual CNC machining system of claim 24, wherein the corresponding operation template further comprises a correction procedure, which is associated with the permitted parameter range;
such that the virtual CNC manufacturing server is configured to perform an operation correction if the operation validation failed, using the correction procedure of the corresponding operation template, such that the correction procedure updates the at least one parameter to be within the permitted parameter range of the corresponding operation template.

26. The virtual CNC machining system of claim 25, wherein the corresponding logical machine operation is a drilling operation;
wherein the at least one parameter comprises a corresponding dwell time parameter; and wherein the permitted parameter range is specified from a minimum permitted dwell time to a maximum permitted dwell time;
such that the correction procedure is configured to update the corresponding dwell time parameter to the maximum permitted dwell time, when the corresponding dwell time parameter is above the permitted parameter range; and
such that the correction procedure is configured to update the corresponding dwell time parameter to the minimum permitted dwell time, when the corresponding dwell time parameter is below the permitted parameter range.

27. The virtual CNC machining system of claim 25, wherein the correction procedure is performed automatically, without intervention from a user.

28. The virtual CNC machining system of claim 25, wherein the correction procedure is performed subject to a manual confirmation from a user, wherein the correction procedure is performed after the manual confirmation is provided by the user.

29. A virtual computer numerical control (CNC) machining system, comprising:
a virtual CNC manufacturing server, which is configured to edit a logical machine job, wherein the logical machine job comprises:
a logical workpiece, which specifies a physical workpiece; and
a design model, which specifies a manufactured piece for manufacturing from the physical workpiece;
a logical work-holding device, which specifies a physical work-holding device for holding the physical workpiece during the manufacturing a logical machining tool, which specifies a physical machining tool for machining the manufactured piece;
a logical CNC machine, which specifies a physical CNC machine for manufacturing the manufactured piece, when the physical work-holding device with the physical workpiece attached and the physical machining tool are mounted on the physical CNC machine; and
a logical machine program, which comprises a sequence of logical machine operations for manufacturing the physical workpiece with specifications according to the design model.

30. The virtual CNC machining system of claim 29, further comprising:
a plurality of physical CNC machine systems, wherein each corresponding physical CNC machine system comprises:
a corresponding physical CNC machine;
a plurality of physical work-holding devices, each configured to be mounted on the corresponding physical CNC machine;
a plurality of physical machining tools, each configured to be mounted on the corresponding physical CNC machine; and
a plurality of work pieces, each configured to be machined when mounted on the corresponding physical CNC machine.
